(19) United States
(12) Patent Application Publication
(10) Pub. No.: US 2002/0064928 A1
(43) Pub. Date: May 30, 2002

(54) METHOD FOR MANUFACTURING A HIGH-FREQUENCY INTEGRATED CIRCUIT FOR REDUCING CROSS-TALK AND FACILITATING ENERGY STORAGE

(76) Inventor: Theodore W. Houston, Richardson, TX (US)

Correspondence Address: Jacqueline J. Garner, Texas Instruments Incorporated, P. O. Box 655474, M/S 3999, Dallas, TX, 75265, US

(21) Appl. No.: 09/727,197

(22) Filed: Nov. 30, 2000

Related U.S. Application Data
(60) Provisional application No. 60/171,727, filed on Dec. 22, 1999.

(51) Int. Cl. H01L 27/082

(52) U.S. Cl. 438/584

(57) ABSTRACT

A semiconductor device (10, 40, 50, 60) is an integrated circuit which includes a silicon substrate (12) and a silicon film (21) that are coupled to each other by an intermediate structure (16, 18, 62, 67). The intermediate structure includes an insulating material (16, 18, 67). Bonding is used in the region of the intermediate structure in order to effect the coupling of the silicon substrate and film. A radio-frequency circuit (23) is formed on the silicon film, and includes an inductive component (28) and a non-inductive component (26, 27). The insulating material has an effective thickness which is larger beneath the inductive component than beneath the non-inductive component, so as to provide a good ground plane effect as to the non-inductive component, while facilitating a reduced ground plane effect and a high degree of energy storage as to the inductive component.

### TECHNICAL FIELD OF THE INVENTION

This invention relates in general to high-frequency integrated circuits and, more particularly, to the structure and fabrication of integrated circuits that have non-inductive components that need a good ground plane effect to minimize cross talk, and that have inductive components for which it is desirable to maximize energy storage capability.

### BACKGROUND OF THE INVENTION

In an integrated circuit which implements a high-frequency circuit, such as a radio-frequency circuit, there are competing design considerations. For example, it is desirable on one hand to have a good ground plane effect in order to reduce cross talk as to non-inductive components, and in this regard it is desirable to use the semiconductor substrate to provide a low inductance coupling to ground. On the other hand, with respect to inductive components of the high-frequency circuit, it is desirable to have a high “Q” factor, which is an industry standard measure of the capability of an inductive component to store energy. In order to obtain a high Q factor for an inductive component, it is desirable to have below the inductor a relatively thick non-conductive layer that provides a reduced ground plane effect.

In this regard, there is an existing semiconductor technology which is commonly known as silicon on insulator (SOI) technology. In an SOI device, an insulating material such as silicon dioxide or some other dielectric material is effectively sandwiched between an underlying silicon substrate and an overlying silicon film, and the components of the integrated circuit are fabricated on the silicon film. In an SOI device, the insulating layer is sometimes referred to as a buried oxide (BOX) layer. One known technique of creating an SOI device is to take bulk silicon and implant oxygen into the device through the top surface, the oxygen combining with the silicon so as to form a layer of silicon dioxide a small distance below the top surface, which is the BOX layer. An alternative technique is to take a silicon substrate and a silicon film, grow a layer of oxide on at least one of them, and then couple them together with the oxide therebetween by carrying out a bonding operation in the region of the oxide.

As mentioned above, it is desirable in a high-frequency circuit that inductive components be above a non-conducting layer, in order to increase the Q factor for these components. Since the insulating layer of an SOI device is non-conductive, it has been previously recognized that it could be advantageous to use SOI technology to implement high-frequency circuits. As a practical matter, however, some difficulties have been encountered in trying to use SOI technology to achieve a high Q factor for inductive components of high-frequency circuits.

For example, in existing SOI technologies, the insulating layer is typically less than 3μm in thickness, which is not sufficiently thick to provide a high Q factor for an inductive component of a high-frequency circuit. A thickness on the order of approximately 10 μm would be appropriate in order to obtain a suitably high Q factor. Although it is possible to increase the effective thickness of the insulating layer by using a substrate which has a high level of resistivity, the increased thickness of the insulating layer and the resistivity of the substrate prevent the substrate from satisfying the competing consideration of providing a good ground plane effect for non-inductive components of the high-frequency circuit. An alternative technique for achieving a high Q factor for inductive components is to utilize a silicon on sapphire technology, but this also fails to provide the good ground plane effect needed for non-inductive components of the high-frequency circuit.

A further consideration with respect to typical SOI technology is that the coefficient of thermal expansion (CTE) for the silicon dioxide insulating layer is different from that of the silicon substrate and the silicon film. While this is not a significant factor when the insulating layer is relatively thin, it become a more critical consideration when the thickness of the insulating layer is increased, because it tends to increase the tendency of the insulating material to induce warping of the overall semiconductor device.

Yet another consideration is that high-frequency circuits tend to produce a substantial amount of heat, and it is beneficial to be able to dissipate a significant portion of that heat through the substrate. However, increasing the thickness of the insulating layer across the entire device not only tends to degrade the desired ground plane effect, as discussed above, but also decreases the thermal conductivity from the silicon film through the insulating layer to the silicon substrate, thereby degrading the ability of the integrated circuit to dissipate heat from the circuitry through the substrate.

For reasons which include those discussed above, known approaches for implementing high-frequency circuits in SOI technology have been generally adequate for their intended purposes, but have not been satisfactory in all respects.

### SUMMARY OF THE INVENTION

From the foregoing, it will be appreciated that a need has arisen for a semiconductor device, and a method of making it, in which a high-frequency circuit enjoys a high Q factor for inductive components, and a good ground plane effect for non-inductive components.

According to one form of the present invention, a method is provided to address this need, and involves fabricating a first member which is made of a semiconductor material and which has thereon a first surface; fabricating a second member which is made of a semiconductor material and which has thereon a second surface; forming in the first member a region which extends into the first member from the first surface, and which is less conductive than a portion of the semiconductor material of the first member disposed adjacent to the region; and fabricating between the first and second surfaces an intermediate structure which couples the first and second members together, the intermediate structure including a layer of an insulating material.

According to a different form of the present invention, an apparatus is provided to address the need, and includes a first member made of a semiconductor material and having thereon a first surface; a second member made of a semiconductor material and having thereon a second surface; a region which extends into the first member from the first surface, the region being less conductive than a portion of the semiconductor material of the first member disposed adjacent to the region; and an intermediate structure which is disposed between and couples the first and second members, the intermediate structure including a layer of an insulating material.

### BRIEF DESCRIPTION OF THE DRAWINGS

A better understanding of the present invention will be realized from the detailed description which follows, taken in conjunction with the accompanying drawings, in which:

FIG. 1 is a diagrammatic sectional side view of a first embodiment of a semiconductor device which embodies features of the present invention, and which is fabricated according to a method that embodies features of the present invention;

FIG. 2 is a diagrammatic sectional side view of a semiconductor device which is an alternative embodiment of the semiconductor device of FIG. 1, and which is fabricated according to an alternative embodiment of the method used to fabricate the device of FIG. 1;

FIG. 3 is a diagrammatic sectional side view of yet another semiconductor device which is an alternative embodiment of the semiconductor device of FIG. 1, and which is fabricated according to a different alternative embodiment of the method used to fabricate the device of FIG. 1; and

FIG. 4 is a diagrammatic sectional side view of still another semiconductor device which is an alternative embodiment of the device of FIG. 1, and which is fabricated according to yet another alternative embodiment of the method used to fabricate the device of FIG. 1.

### DETAILED DESCRIPTION OF THE INVENTION

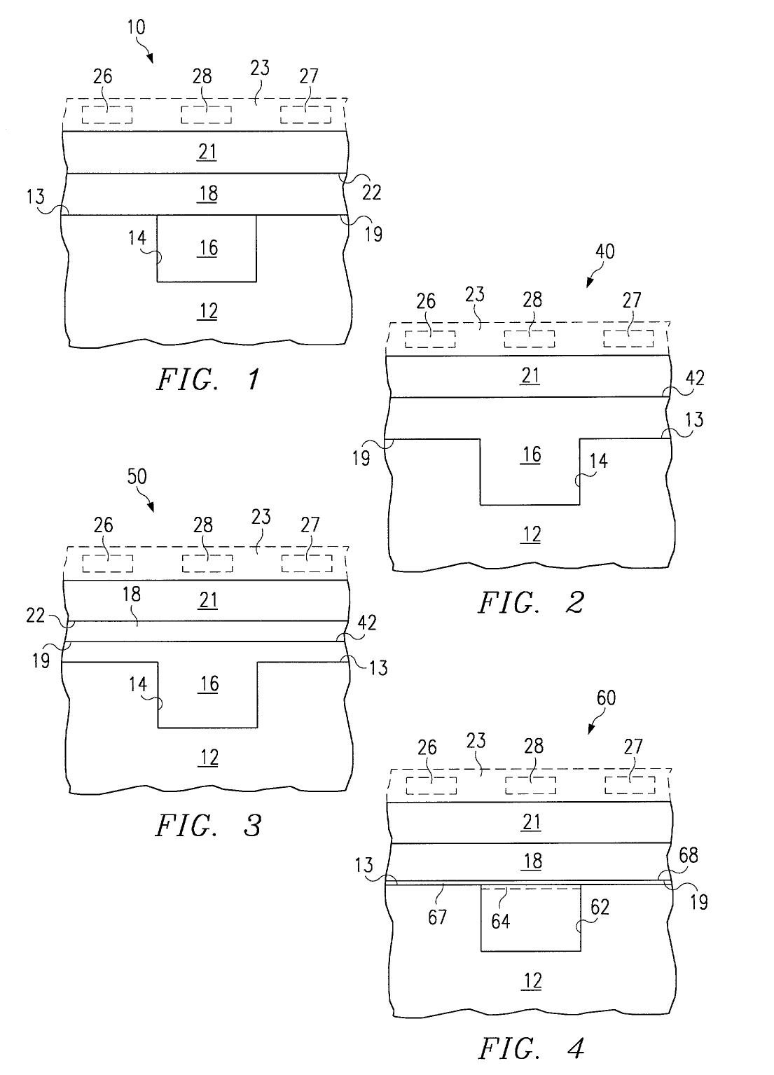

FIG. 1 is a diagrammatic sectional side view of a semiconductor device which is an integrated circuit 10 that embodies the present invention, and which is fabricated according to a method that includes features of the present invention. The integrated circuit 10 includes a substrate 12 made of a silicon semiconductor material, the substrate 12 having a top surface 13.

During fabrication of the integrated circuit 10, a recess 14 is formed in the substrate 12, in a manner so that the recess 14 extends downwardly into the substrate 12 from the top surface 13 of the substrate 12. In the disclosed embodiment of FIG. 1, the recess 14 is formed through use of an appropriate patterned etch. An insulating material 16 is then deposited over the device 10 so as to fill the recess 14. In the disclosed embodiment, the insulating material 16 is silicon dioxide. Thereafter, a planarization procedure is carried out in order to remove any portion of the insulating material 16 which is above the top surface 13 of the substrate 12. Stated differently, the planarization removes portions of the material 16 which are above the top surface 13, so that the top surface of the material 16 is coplanar with the top surface 13 of the substrate 12. In the disclosed embodiment, the planarization is carried out using a known planarization technique, such as a chemical mechanical polishing (CMP) technique, or an etching technique.

Next, a layer 18 of an insulating material is formed on a bottom surface 22 of a film 21 that is made of a silicon semiconductor material. The insulating layer 18 is made of silicon dioxide, and is grown on the surface 22. The bottom surface 19 of the insulator layer 18 should inherently be substantially planar, as a result of the fact that the layer 18 was created by being grown on the surface 22. Consequently, planarization of the surface 19 using a separate planarization step should not be needed.

Then, the bottom surface 19 of the insulating layer 18 is bonded to the top surface 13 of the substrate 12, which effectively includes the coplanar top surface of the insulating material 16. Bonding of the surfaces 13 and 19 is carried out using a bonding technique which is known in the art, and which is therefore not described in detail here. Prior to and during the bonding, the film 21 is substantially thicker than depicted in FIG. 1. After the bonding is completed, so that the substrate 12 and insulating layer 18 provide support for the film 21, the film 21 is thinned or cleaved in a manner known in the art, so that the portion thereof which remains bonded to the insulating layer 18 and the substrate 12 is a relatively thin slice consistent with the diagrammatic view of FIG. 1. The resulting device 10 has an effective insulating layer of varying thickness which is defined by 18 and 16, and which is sandwiched between a silicon semiconductor substrate 12 and a silicon semiconductor film 21. The device 10 thus falls within the class of devices commonly known as silicon on insulator (SOI) devices.

Subsequently, as shown diagrammatically at 23, a high-frequency circuit is fabricated on the upper side of the silicon film 21. In the disclosed embodiment of FIG. 1, the circuit 23 is a radio frequency circuit, but it could alternatively operate in some other high frequency range. The radio frequency circuit 23 includes a number of circuit components, three of which are shown diagrammatically at 26-28. The circuit components 26 and 27 are non-inductive components which are each disposed over a portion of the substrate 12 other than the region which includes the insulating material 16, whereas the circuit component 28 is an inductive component which is disposed directly above the insulating material 16.

In FIG. 1, the effective thickness of the insulating layer is greater below the inductive component 28, where the insulating layer is essentially defined by the cumulative thickness of the layer 18 and the material 16. As a result, the inductive component 28 enjoys a relatively high “Q” factor, which is an industry standard measure of the capability of a component to store energy. In contrast, the effective thickness of the insulating layer is smaller below each of the non-inductive components 2627, where the effective thickness corresponds to just the thickness of the layer 18 by itself. As a result, the substrate 12 is effectively closer to the non-inductive components 26-27 than to the inductive component 28, so that the substrate 12 causes the non-inductive components 26-27 to enjoy a relatively good ground plane effect that reduces cross talk, while the component 28 enjoys a relatively high Q factor and a reduced ground plane effect.

FIG. 2 is a diagrammatic sectional side view similar to FIG. 1, but showing a semiconductor device 40 which is an alterative embodiment of the semiconductor device 10 of FIG. 1. The structure and fabrication of the device 40 are similar to the structure and fabrication described above for the device 10, except as follows. After creation of the recess 14 in the silicon substrate 12, and the deposition or growth on the substrate 12 of a layer of insulating material 16 such as silicon dioxide, the layer 16 is not planarized all the way down to a level corresponding to the top surface 13 of the substrate 12. Instead, the layer 16 is planarized in a manner so that it has thereon an upwardly facing surface 42, which is parallel to and spaced above the top surface 13 of the substrate 12. In addition, no separate oxide layer of the type shown at 18 in FIG. 1 is grown on the bottom surface 22 of the silicon film 21. Instead, the top surface 42 of the layer 16 is bonded directly to the bottom surface 22 of the silicon film 21, using known bonding techniques. Thereafter, the radio-frequency circuit 23 is fabricated on the silicon film 21.

In the device 40, the layer 16 is structurally and functionally equivalent to the combined layer 18 and material 16 in the device 10 of FIG. 1. The primary difference is that, in the device 10 of FIG. 1, bonding occurs at the top surface 13 of the substrate 12, whereas in the device 40 of FIG. 2, bonding occurs at the bottom surface 22 of the silicon film 21.

FIG. 3 is a diagrammatic sectional side view similar to FIG. 1, but showing a semiconductor device 50 which is a further alternative embodiment of the semiconductor device 10 of FIG. 1. The structure and fabrication of the semiconductor device 50 are similar to the structure and fabrication described above for the device 10 of FIG. 1, except as follows. When the layer of insulating material 16 is deposited on the substrate 12, it is not planarized all the way down to the level of the top surface 13 of the substrate 12. Instead, in a manner similar to that described above for the embodiment of FIG. 2, it is planarized so as to define an upwardly facing top surface 42 which is parallel to and spaced above the top surface 13 of the substrate 12. In FIG. 3, the surface 42 is closer to the top surface 13 than in FIG. 2. Next, the insulating layer 18 is formed on the underside of the silicon film 21, in a manner similar to that described above for the embodiment of FIG. 1, except that the layer 18 is slightly thinner in FIG. 3 than in FIG. 1. Thereafter, the bottom surface 19 of insulating layer 18 is bonded to the top surface 42 of the insulating layer 16, using known bonding techniques. In the resulting device 50 of FIG. 3, the layers 16 and 18 are collectively equivalent to the layer 18 and material 16 in the device 10 of FIG. 1, and are also equivalent to the layer 16 in the device 40 of FIG. 2.

In a variation of FIG. 3, which is not illustrated, the portion 16 could be made from a nonconductive material different from the silicon dioxide material used in the embodiment of FIG. 3. For example, the portion 16 could be made from an intrinsic silicon material such as amorphous silicon. Optionally, a diffusion barrier could be provided between the material 16 and the substrate 12. Such a diffusion barrier could be made of a material such as tungsten, or tungsten nitride. Alternatively, the diffusion barrier could be silicon dioxide, or a material such as SiNₓO_{y}.

FIG. 4 is a diagrammatic sectional side view of a further semiconductor device 60, which is yet another alternative embodiment of the device 10 of FIG. 1. The structure and fabrication of the device 60 are similar to the structure and fabrication described above in association with the device 10 of FIG. 1, except as follows.

A region 62 of porous silicon semiconductor material is formed within the silicon semiconductor substrate 12, so as to extend into the substrate 12 from the top surface 13 thereof. The region 62 may be formed using a known technique, for example by implanting impurities into the region 62 of substrate 12 through the top surface 13, and then carrying out a selective etch which is effective primarily where the impurities are located. Although the region 62 of porous silicon is still a semiconductor material, the introduction of porosity causes it to have a lower degree of conductivity than the rest of the substrate 12.

In order to thereafter facilitate a good bond between the substrate 12 and the insulator layer 18, the top portion of the porous region 62, which is indicated diagrammatically at 64, may optionally be fused, for example by annealing the device 60 in a hydrogen atmosphere. Fusing the top portion 64 of the region 62 ensures that the top surface 13 of the substrate 12 has a relatively uniform characteristic across its entire extent, including the portion of the surface 13 which is provided directly on the region 62, and the portion of the surface 13 which is provided directly on the substrate 12.

Another optional technique to facilitate a secure bond between the substrate 12 and the insulating layer 18 is to fabricate a very thin layer 67 of intrinsic silicon on the top surface 13 of the substrate 12. The layer 67 may, for example, be an epi layer, an amorphous silicon material, or a polysilicon material. Since, in the disclosed embodiment, the layer 67 is intrinsic silicon, it is effectively a non-conductor, and thus functions as an insulator for purposes of the present invention. The layer 67 has a top surface 68 which is then bonded to the bottom surface 19 of the insulating layer 18, using known bonding techniques. The top surface 68 of the layer 67 has a substantially uniform characteristic across its entire extent, which facilitates a strong and uniform bond between the surface 68 and the surface 19. In the device 60 of FIG. 4, the layers 18 and 67 and the material 16 are collectively equivalent to the layer 18 and material 16 in the device 10 of FIG. 1, the layer 16 in semiconductor device 40 of FIG. 2, and the layers 16 and 18 in the device 50 of FIG. 3.

The disclosed embodiment of FIG. 4 uses both fusing at 64 and the provision of the layer 67, but as noted above these features are both optional. Variations of the embodiment of FIG. 4 include use of the fusing at 64 but not the layer 67, use of the layer 67 but not the fusing at 64, or omission of both the layer 67 and the fusing at 64.

As discussed above, the layer 67 in the disclosed embodiment of FIG. 4 is some form of intrinsic silicon, and is thus non-conductive. However, the layer 67 could alternatively be a material having some limited degree of conductivity, such as a doped silicon material. However, the layer 67 is very thin, and the thickness and conductivity are therefore such that the layer 67 does not have the effect of causing any significant reduction in the Q factor enjoyed by the inductive component 28.

In the device 60 of FIG. 4, as described above, the region 62 is porous silicon. After fabrication of the region 62 of porous silicon, and prior to the addition of any other layers on top of the substrate 12, it would be optionally and alternatively possible to subject the top surface 13 of the device 12 to an oxidation process. The region 62 of porous silicon will oxidize substantially more quickly than the solid silicon material outside the region 62. As a result of the oxidation, the material inside the porous region 62 will be converted from silicon to porous silicon dioxide, which of course is an insulator. Optionally, the oxidation process could be controlled so that only a portion of the porous silicon becomes oxidized, but for purposes of convenience and clarity in the present discussion, it is assumed that all of the porous silicon becomes oxidized.

As is known in the art, silicon takes up less space before it is oxidized and becomes silicon dioxide. Consequently, after oxidation, the resulting silicon dioxide in region 62 may still be porous to some extent, or may be relatively solid. Assuming for the moment that the region 62 still has a degree of porosity after oxidation, the resulting device 60 of FIG. 4 will be structurally equivalent to the device 10 of FIG. 1, except that the silicon dioxide in the region 62 will be porous, whereas the silicon dioxide at 16 in the device 10 of FIG. 1 is effectively solid. In the event that the porous silicon in the region 62 is subjected to oxidation in this manner, the optional fusing at 64 and the optional layer 67 can be omitted.

In the foregoing discussion of the embodiments of FIGS. 1-4, it is explained that the materials 16 and 18, and the material of region 62 if oxidized, are silicon dioxide. However, as an alternative to the use of silicon dioxide for these regions, it would be possible to use oxynitride (SiOₓN_{y}). The coefficient of thermal expansion (CTE) of silicon is more closely matched to the CTE of oxynitride than to the CTE of silicon dioxide. Consequently, when oxynitride is used, a layer or region of insulating material, such as those at 16 and/or 18, can be somewhat thicker than would be the case for silicon dioxide, because the close match between the CTEs of silicon and oxynitride means that there is less tendency for the oxynitride material to induce warpage in the resulting device that would be the case for silicon dioxide.

The present invention provides a number of technical advantages. One such technical advantage is that, in a silicon on insulator (SOI) technology, a good ground plane effect with low inductance coupling to ground is obtained, so as to reduce cross talk as to non-inductive components of a high-frequency circuit. At the same time, a greater effective thickness of the insulating layer is obtained in the region of inductive components, so that the inductive components enjoy a reduced ground plane effect and a relatively high Q factor. A further advantage is that, since the increased effective thickness of the insulating layer associated with inductive components is only a fraction of the total area of the device, there is little or no tendency for this non-conductive material to induce warping in the device. In any event, by using oxynitride as the non-conductive material, a good match can be achieved between the coefficients of thermal expansion of silicon and oxynitride, which further reduces any tendency of the insulating layer to induce warping.

Yet another technical advantage is that, while a high Q factor is obtained for inductive components, and a good ground plane effect is obtained for non-inductive components, the device has relatively good thermal conductivity in the region of most components of the high-frequency circuit, so as to facilitate the dissipation of heat away from the circuit through the semiconductor substrate. Still another advantage is that semiconductor devices embodying the present invention can be fabricated using bonding techniques in order to couple spaced semiconductive members through an intermediate structure, which facilitates fabrication and avoids difficulties that would be involved in attempting to fabricate devices according to the invention in bulk semiconductor material.

Although several selected embodiments have been illustrated and described in detail, it will be recognized that they are merely exemplary, and that various substitutions and alterations can be made therein without departing from the spirit and scope of the present invention, as defined by the following claims.

What is claimed is:

1. A method of making a semiconductor device, comprising the steps of:
fabricating a first member which is made of a semiconductor material and which has thereon a first surface;
fabricating a second member which is made of a semiconductor material and which has thereon a second surface;
forming in said first member a region which extends into said first member from said first surface, and which is less conductive than a portion of said semiconductor material of said first member disposed adjacent to said region; and
fabricating between said first and second surfaces an intermediate structure which couples said first and second members together, said intermediate structure including a layer of an insulating material.

2. A method according to claim 1, wherein said step of fabricating said intermediate structure includes the step of forming said intermediate structure on said first surface, and thereafter bonding said second surface to a side of said intermediate structure opposite from said first member.

3. A method according to claim 1, wherein said step of fabricating said intermediate structure includes the step of forming said intermediate structure on said second surface, and thereafter bonding said first surface to a side of said intermediate structure opposite from said second member.

4. A method according to claim 1, wherein said step of fabricating said intermediate structure includes the step of forming a first portion of said intermediate structure on said first surface, forming a second portion of said intermediate structure on said second surface, and then bonding said first and second portions of said intermediate structure to each other.

5. A method according to claim 1, wherein said step of forming said region is carried out by creating a recess which opens into said first member from said first surface thereon, and then filling said region with a material which is substantially insulating.

6. A method according to claim 1, wherein said step of said forming said region is carried out by forming said region as a porous portion of said semiconductor material of said first member.

7. A method according to claim 6, wherein said semiconductor material of said first member is silicon, and including the step of oxidizing said porous portion of said first member.

8. A method according to claim 6, wherein said step of fabricating said intermediate structure includes a step which effects fusing of a portion of said region adjacent said first surface.

9. A method according to claim 6, wherein said step of fabricating said intermediate structure includes the steps of forming on said first surface a thin layer of material which has on a side thereof remote from said first member a third surface, forming on said second surface a further portion of said intermediate structure having a fourth surface thereon, and then bonding said third surface to said fourth surface.

10. A method according to claim 9, wherein said step of forming said thin layer is carried out by using a material which is substantially insulating.

11. A method according to claim 1, including the step of fabricating on one of said first and second members a high-frequency circuit which includes a first section aligned with said region of said first member and a second section aligned with said portion of said first member which is adjacent said region, said first section of said circuit including an inductive component.

12. An apparatus comprising a semiconductor device which includes:
a first member made of a semiconductor material and having thereon a first surface;
a second member made of a semiconductor material and having thereon a second surface;
a region in said first member which extends into said first member from said first surface, said region being less conductive than a portion of said semiconductor material of said first member disposed adjacent to said region; and
an intermediate structure which is disposed between and couples said first and second members, said intermediate structure including a layer of an insulating material.

13. An apparatus according to claim 12, wherein said insulating material is an oxynitride.

14. An apparatus according to claim 12, wherein said region is a porous portion of said semiconductor material of said first member.

15. An apparatus according to claim 14, wherein a portion of said region disposed adjacent said first surface has been fused.

16. An apparatus according to claim 14, wherein said intermediate structure includes a thin layer of material which is disposed on said first surface, which is substantially an insulator, and which has a third surface on a side thereof opposite from said first member; and wherein said intermediate structure further includes a portion which is disposed on said second surface and which has a fourth surface on a side thereof opposite from said second member, said third surface being bonded to said fourth surface.

17. An apparatus according to claim 12, wherein said region of said first member is a porous portion of said semiconductor material of said first member which has been oxidized.

18. An apparatus according to claim 12, including on one of said first and second members a high-frequency circuit which includes a first section aligned with said region of said first member and a second section aligned with said portion of said first member which is adjacent said region, said first section of said circuit including an inductive component.
